(19) United States
(12) Patent Application Publication
(10) Pub. No.: US 2019/0189970 A1
(43) Pub. Date: Jun. 20, 2019

(54) DISPLAY PANEL, DISPLAY APPARATUS AND MANUFACTURING METHOD THEREOF

(71) Applicant: Wuhan China Star Optoelectronics Semiconductor Display Technology Co., Ltd., Wuhan, HB (CN)

(72) Inventor: Jian Ye, Shenzhen (CN)

(21) Appl. No.: 15/749,010

(22) PCT Filed: Jan. 8, 2018
(86) PCT No.: PCT/CN2018/071694

§ 371 Date: Jan. 30, 2018

(30) Foreign Application Priority Data
Dec. 14, 2017 (CN) 201711372344.5

(51) Int. Cl. H01L 51/52; G06F 3/044; G06F 3/041; H01L 27/32; H01L 51/00

(52) U.S. Cl. CPC H01L 51/5281; G06F 3/044; G06F 2203/04103; H01L 27/323; H01L 51/0097; G06F 3/0412

(57) ABSTRACT

The present disclosure provides a display panel, a display apparatus and a manufacturing method thereof. The display panel include: a display screen; a circular polarizer, located at a light exit side of the display screen; touch control electrode layer, located between the display screen and the circular polarizer, inside the circular polarizer or at a light exit side of the circular polarizer. According to the present disclosure, the touch control electrode layer is set at one of two sides of the circular polarizer or inside the circular polarizer, such that the touch screen does not have to be manufactured individually, and the total thickness of the display panel may be reduced. Therefore, the present disclosure may contribute to the improvement of the flexibility of the display panel.

### CROSS-REFERENCE TO RELATED APPLICATIONS

The present application is a 35 U.S.C. § 371 National Phase conversion of International (PCT) patent application No. PCT/CN2018/071694, filed on Jan. 8, 2018, which claims foreign priority of Chinese patent application No.201711372344.5, filed on Dec. 14, 2017 in the State Intellectual Property Office of China, the contents of all of which are hereby incorporated by reference.

### TECHNICAL FIELD

The present disclosure generally relates to the display field, and in particular to a display panel, a display apparatus and a manufacturing method thereof.

### BACKGROUND

A touch screen is direct and efficient human-machine interface device which largely improves the efficiency and the convenience of the human-machine communication. Among various touch control technologies, capacitive touch control is widely used because a touch screen using this technology is light and thin.

The touch screen is usually manufactured individually and then attached on the surface of a display panel with optical transparent glue so as to form the complete touch control display apparatus. Since the individually-manufactured touch screen is thick, when attached on the display panel it may increase the thickness of the display apparatus. Thus, this kind of display apparatus cannot be very light, thin and flexible.

### SUMMARY

The present disclosure provides a display panel, a display apparatus and a manufacturing method thereof to solve the above-mentioned problem.

To solve the above-mentioned problem, a technical scheme adopted by the present disclosure is to provide a display panel, including: a display screen; a circular polarizer, located at a light exit side of the display screen; a touch control electrode layer, located between the display screen and the circular polarizer, inside the circular polarizer or at a light exit side of the circular polarizer.

To solve the above-mentioned problem, another technical scheme adopted by the present disclosure is to provide a manufacturing method for a display panel, including: forming a touch control electrode layer on a display screen, and forming a circular polarizer on the touch control electrode layer; or forming a circular polarizer on a display screen, wherein the circular polarizer comprises a touch control electrode layer; or forming a circular polarizer on a display screen, and forming a touch control electrode layer on the circular polarizer.

To solve the above-mentioned problem, another technical scheme adopted by the present disclosure is to provide a display apparatus including the above-mentioned display panel.

According to the present disclosure, the touch control electrode layer is set at one of two sides of the circular polarizer or inside the circular polarizer, such that the touch screen does not have to be manufactured individually, and the total thickness of the display panel may be reduced. Therefore, the present disclosure may contribute to the improvement of the flexibility of the display panel.

### BRIEF DESCRIPTION OF THE DRAWINGS

To describe the technical solutions in the embodiments of the present disclosure more clearly, the accompanying drawings required for describing the embodiments will now be briefly introduce as follows. Apparently, the accompanying drawings in the following description show merely some embodiments of the present disclosure. For those skilled in the art, other drawings can also be obtained according to these drawings without any creative efforts.

FIG. 1 is a schematic diagram of a display panel according to an embodiment of the present disclosure.

FIG. 2 is a schematic diagram of a display panel according to an embodiment of the present disclosure.

FIG. 3 is a schematic diagram of a display panel according to an embodiment of the present disclosure.

FIG. 4 is a schematic diagram of a conducting bridge according to an embodiment of the present disclosure.

FIG. 5 is a schematic diagram of a display panel according to another embodiment of the present disclosure.

FIG. 6 is a schematic diagram of a display panel according to another embodiment of the present disclosure.

FIG. 7 is a schematic diagram of a display panel according to another embodiment of the present disclosure.

FIG. 8 is a schematic diagram of a display panel according to an embodiment of the present disclosure.

FIG. 9 is a flow chart of a manufacturing method for a display panel according to an embodiment of the present disclosure.

FIG. 10 is a schematic diagram of a display apparatus according to an embodiment of the present disclosure.

### DETAILED DESCRIPTION

The disclosure will now be described in detail with reference to the accompanying drawings and examples. Apparently, the embodiments described below are only a part but not all of the embodiments of the present disclosure. All other embodiments obtained by a person of ordinary skill in the art based on the embodiments of the present disclosure without creative efforts shall fall within the protection scope of the present invention.

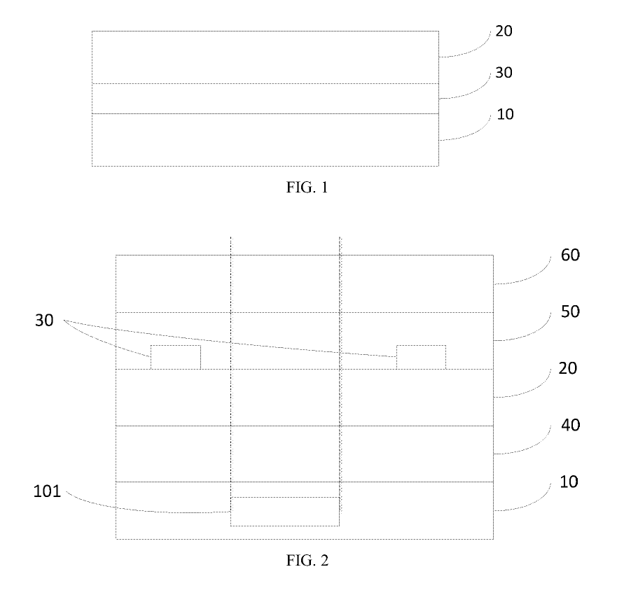

Referring to FIG. 1, the display panel according to an embodiment of the present disclosure may include:

a display screen 10, wherein the display screen 10 may be an OLED (organic light-emitting diode) screen;

a circular polarizer 20, located at the light exit side of the display screen 10;

a touch control electrode layer 30, located at the light exit side of the circular polarizer 20.

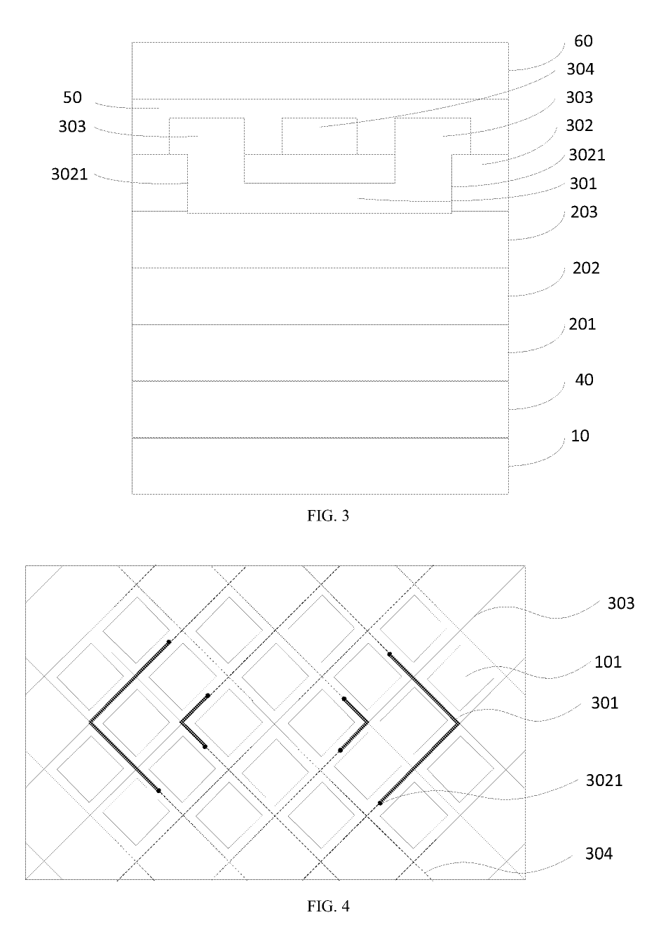

Referring to FIGS. 1-4, the display panel may further include a third glue layer 50 and a protection cap 60 for protecting the display panel.

In this embodiment, the circular polarizer 20 may be attached with the display screen 10 by a first glue layer 40. The circular polarizer 20 may include:

a phase compensation film layer 201 located at a side of the first glue layer 40 far away from the display screen 10, wherein the phase compensation film layer 201 may be a ¼λ, phase compensation film;

a second glue layer 202 located at a side of the phase compensation film layer 201 far away from the first glue layer 40, wherein, the first glue layer 40 and the second glue layer 202 may both include the OCA (optical clear adhesive);

a linear polarizer 203 located at a side of the second glue layer 202 far away from the phase compensation film layer 201.

In one embodiment, the linear polarizer 203 may include TAC (triacetyl cellulose) and PVA (polyvinyl alcohol). The thickness of the TAC may be 0-40 μm. The thickness of the PVA may be 0-20 μm.

In this embodiment, the touch control electrode layer 30 may be located at a side of the linear polarizer 203 far away from the second glue layer 202.

The touch control electrode layer 30 may include:

a conducting bridge 301 located at a side of the linear polarizer 203 far away from the second glue layer 202, wherein the conducting bridge 301 may include titanium, aluminum or other metal;

an insulating layer 302 covering the conducting bridge 301, wherein the insulating layer 302 defines two via holes 3021 located corresponding to the two electrodes of the conducting bridge 30, optionally the insulating layer 302 may include materials such as silicon nitride;

at least two touch-driving electrodes 303 located at a side of the insulating layer 302 far away from the conducting bridge 301, and connected to the conducting bridge 301 through the via holes 3021;

a touch-sensing electrode 304 located at a same layer as the touch-driving electrodes 303, wherein a gap is defined between the touch-sensing electrode 304 and the touch-driving electrodes 303 such that an induced capacitor is formed between the touch-sensing electrode 304 and the touch-driving electrodes 303.

In one embodiment, the touch-driving electrodes 303 and the touch-sensing electrode 304 may have a metal mesh configuration. The mesh lines may be located corresponding to the non-light emitting area of the display screen 10 while the mesh openings may be located corresponding to the pixel light emitting area 101 of the display screen 10.

In one embodiment, the width of the touch-driving electrode 303 and the touch-sensing electrode 304 may be less than or equal to 3 μm. The distance between adjacent pixel light emitting areas 101 may be 18 to 20 μm.

In one embodiment, the touch-driving electrode 303 and the touch-sensing electrode 304 may include titanium, aluminum or other metal.

According to the present disclosure, the touch control electrode layer may be set at a sides of the circular polarizer, such that the touch screen does not have to be manufactured individually, and the total thickness of the display panel may be reduced. Therefore, the present disclosure may contribute to the improvement of the flexibility of the display panel.

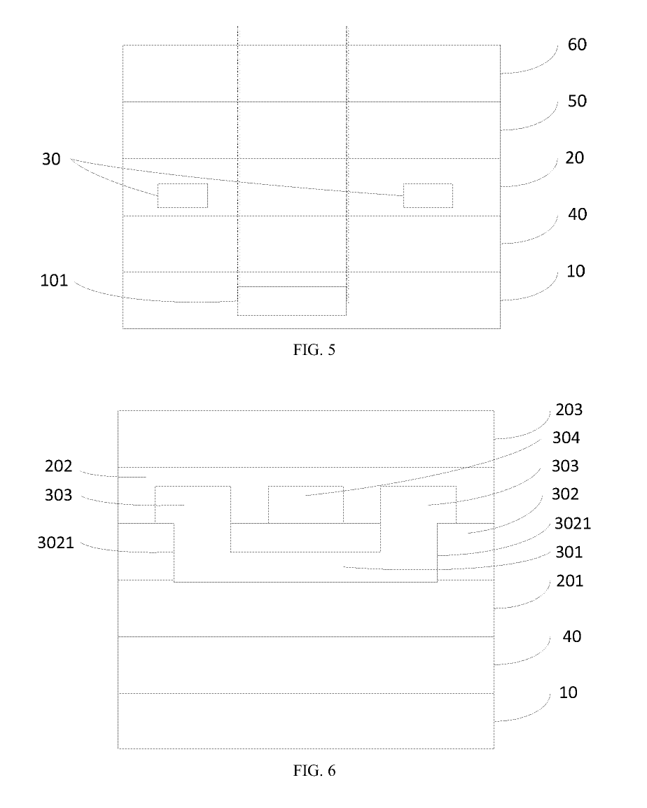

Referring to FIGS. 5 and 6, according to another embodiment of the present disclosure, the display panel may include the above-mentioned display screen 10, the circular polarizer 20 and the touch control electrode 30. However, in this embodiment, the touch control electrode layer 30 may be located inside the circular polarizer 20, that is to say, between the phase compensation film layer 201 and the second glue layer 202.

In one embodiment, the touch-driving electrodes 303 and the touch-sensing electrode 304 may have a metal mesh configuration. The mesh lines may be located corresponding to the non-light emitting area of the display screen 10 while the mesh openings may be located corresponding to the pixel light emitting area 101 of the display screen 10.

According to the present disclosure, the touch control electrode layer may be set inside the circular polarizer, such that the touch screen does not have to be manufactured individually, and the total thickness of the display panel may be reduced. Therefore, the present disclosure may contribute to the improvement of the flexibility of the display panel.

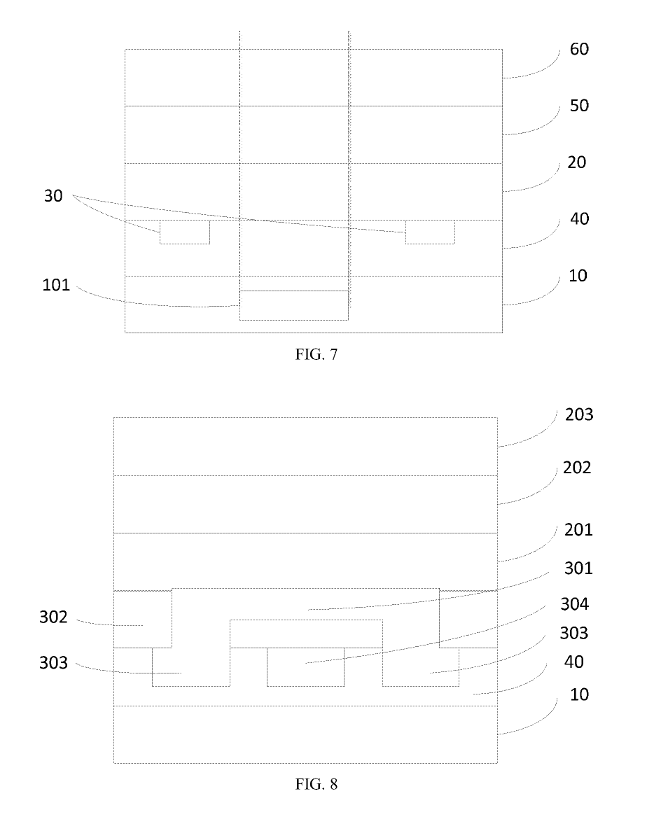

Referring to FIGS. 7 and 8, the display panel according to another embodiment of the present disclosure may include the above-mentioned display screen 10, the circular polarizer 20 and the touch control electrode 30. However, in this embodiment, the touch control electrode layer 30 may be located between the display screen 10 and the circular polarizer 20, that is to say, between the first glue layer 40 and the phase compensation film layer 201.

In one embodiment, the touch-driving electrodes 303 and the touch-sensing electrode 304 may have a metal mesh configuration. The mesh lines may be located corresponding to the non-light emitting area of the display screen 10 while the mesh openings may be located corresponding to the pixel light emitting area 101 of the display screen 10.

According to the present disclosure, the touch control electrode layer may be set at a side of the circular polarizer, such that the touch screen does not have to be manufactured individually, and the total thickness of the display panel may be reduced. Therefore, the present disclosure may contribute to the improvement of the flexibility of the display panel.

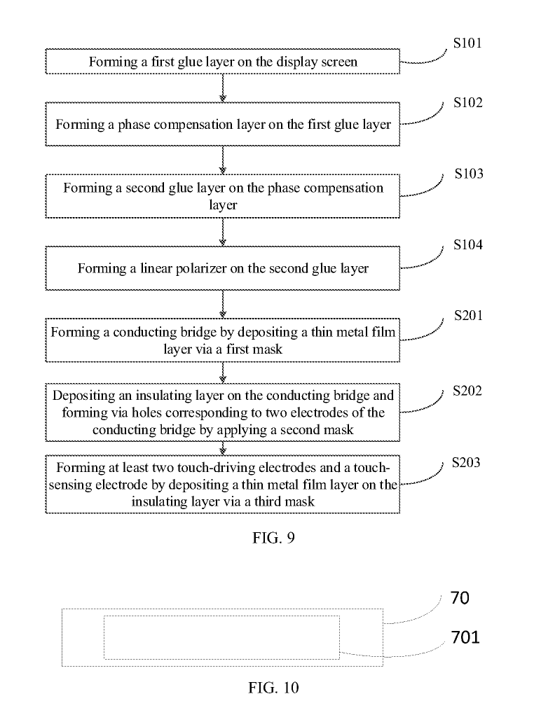

Referring to FIG. 9, the manufacturing method according to an embodiment of the present disclosure may include:

forming a touch control electrode layer on a display screen, and forming a circular polarizer on the touch control electrode layer; or

forming a circular polarizer on a display screen, wherein the circular polarizer comprises a touch control electrode layer; or

forming a circular polarizer on a display screen, and forming a touch control electrode layer on the circular polarizer.

Specifically, S101: Forming a first glue layer on the display screen.

S102: Forming a phase compensation film layer on the first glue layer.

S103: Forming a second glue layer on the phase compensation film layer.

S104: Forming a linear polarizer on the second glue layer.

S201: Forming a conducting bridge at a side of the linear polarizer far away from the second glue layer, or at one of two sides of the phase compensation film layer by depositing a thin metal film layer via a first mask.

S202: Depositing an insulating layer on the conducting bridge and forming via holes corresponding to two electrodes of the conducting bridge by applying a second mask.

S203: Forming at least two touch-driving electrodes and a touch-sensing electrode by depositing a thin metal film layer on the insulating layer via a third mask, wherein the at least two touch-driving electrodes are connected to the conducting bridge through the via holes, a gap is defined between the touch-sensing electrode and the touch-driving electrodes such that an induced capacitor is formed between the touch-sensing electrode and the touch-driving electrodes.

Optionally, PVD (physical vapor deposition) or CVD (chemical vapor deposition) may be applied for depositing the thin metal film layer or the insulating layer. Masks may be employed during the exposure, develop and etch process to form the conducting bridge, the via holes or the touch control electrodes.

In this embodiment, a protection cap may be formed on the touch control electrode layer for protecting the display panel.

According to the present disclosure, the touch control electrode layer may be set at a side of the circular polarizer, such that the touch screen does not have to be manufactured individually, and the total thickness of the display panel may be reduced. Therefore, the present disclosure may contribute to the improvement of the flexibility of the display panel.

Referring to FIG. 10, the display apparatus 70 according to an embodiment of the present disclosure may include the above-mentioned display panel 701.

The display panel 701 of the display apparatus 70 as set forth will not be described hereon.

According to the present disclosure, the touch control electrode layer may be set at a side of the circular polarizer, such that the touch screen does not have to be manufactured individually, and the total thickness of the display panel may be reduced. Therefore, the present disclosure may contribute to the improvement of the flexibility of the display panel.

The foregoing is merely embodiments of the present disclosure, and is not intended to limit the scope of the disclosure. Any transformation of equivalent structure or equivalent process which uses the specification and the accompanying drawings of the present disclosure, or directly or indirectly application in other related technical fields, are likewise included within the scope of the protection of the present disclosure.

1. A display apparatus, comprising a display panel, wherein the display panel comprises:
an organic light-emitting diode (“OLED”) display screen;
a first glue layer on a light exit side of the OLED display screen; and
a circular polarizer, adhered to the OLED display screen via the first glue layer, wherein the circular polarizer comprises:
a phase compensation film layer adhered to the first glue layer opposite to the OLED display screen;
a second glue layer located on a side of the phase compensation film layer opposite to the first glue layer; and
a linear polarizer adhered to the second glue layer; and
a touch control electrode layer, located alternatively between the OLED display screen and the circular polarizer, inside the circular polarizer, or on a light exit side of the circular polarizer.

2. The display apparatus of claim 1, wherein the touch control electrode layer is further located between the first glue layer and the phase compensation film layer when the touch control electrode layer is located between the OLED display screen and the circular polarizer.

3. The display apparatus of claim 1, wherein the touch control electrode layer is further located between the phase compensation film layer and the second glue layer when the touch control electrode layer is located inside the circular polarizer.

4. The display apparatus of claim 1, wherein the touch control electrode layer is further located on a side of the linear polarizer opposite to the second glue layer when the touch control electrode layer is located on the light exit side of the circular polarizer.

5. The display apparatus of claim 1, wherein the touch control electrode layer comprises:
a conducting bridge located on a side of the linear polarizer opposite to the second glue layer when the touch control electrode layer is located on the light exit side of the circular polarizer, or on one side of the phase compensation film layer when the touch control electrode layer is located between the OLED display screen and the circular polarizer or when the touch control electrode layer is located inside the circular polarizer;
an insulating layer covering the conducting bridge, wherein the insulating layer defines two vias corresponding to two electrodes of the conducting bridge;
at least two touch-driving electrodes located on a side of the insulating layer opposite to the conducting bridge, and connected to the conducting bridge through the vias;
a touch-sensing electrode, located on a same layer as the touch-driving electrodes, wherein a gap is defined between the touch-sensing electrode and the touch-driving electrodes so as to form an induced capacitor;
the touch-driving electrodes and the touch-sensing electrode are located corresponding to a non-light emitting area of the OLED display screen.

6. A display panel, comprising:
a display screen;
a circular polarizer, located on a light exit side of the display screen;
a touch control electrode layer, located alternatively between the display screen and the circular polarizer, inside the circular polarizer, or on a light exit side of the circular polarizer.

7. The display panel of claim 6, wherein the circular polarizer is adhered to the display screen via a first glue layer, wherein the circular polarizer comprises:
a phase compensation film layer adhered to the first glue layer opposite to the display screen;
a second glue layer located on a side of the phase compensation film layer opposite to the first glue layer; and
a linear polarizer adhered to the second glue layer.

8. The display panel of claim 7, wherein the touch control electrode layer further is located between the first glue layer and the phase compensation film layer when the touch control electrode layer is located between the display screen and the circular polarizer.

9. The display panel of claim 7, wherein the touch control electrode layer is further located between the phase compensation film layer and the second glue layer when the touch control electrode layer is located inside the circular polarizer.

10. The display panel of claim 7, wherein the touch control electrode layer is further located on a side of the linear polarizer opposite to the second glue layer when the touch control electrode layer is located on the light exit side of the circular polarizer.

11. The display panel of claim 7, wherein the touch control electrode layer comprises:
a conducting bridge located on a side of the linear polarizer opposite to the second glue layer when the touch control electrode layer is located on the light exit side of the circular polarizer, or on one side of the phase compensation film layer when the touch control electrode layer is located between the display screen and the circular polarizer or when the touch control electrode layer is located inside the circular polarizer;
an insulating layer covering the conducting bridge, wherein the insulating layer defines two vias corresponding to two electrodes of the conducting bridge;
at least two touch-driving electrodes located on a side of the insulating layer opposite to the conducting bridge, and connected to the conducting bridge through the vias;
a touch-sensing electrode, located on a same layer as the touch-driving electrodes, wherein a gap is defined between the touch-sensing electrode and the touch-driving electrodes so as to form an induced capacitor;
the touch-driving electrodes and the touch-sensing electrode are located corresponding to a non-light emitting area of the display screen.

12. The display panel of claim 11, wherein the touch-driving electrodes and the touch-sensing electrode have a metal mesh configuration.

13. The display panel of claim 6, wherein the display screen is an organic light-emitting diode (“OLED”) screen.

14. The display panel of claim 6, wherein the phase compensation film layer is a ¼λphase compensation film.

15. A manufacturing method for a display panel, comprising:
forming a touch control electrode layer on a display screen, and forming a circular polarizer on the touch control electrode layer; or
forming a circular polarizer on a display screen, wherein a touch control electrode layer is disposed inside the circular polarizer; or
forming a circular polarizer on a display screen, and forming a touch control electrode layer on the circular polarizer;
wherein forming the circular polarizer comprises:
forming a first glue layer on the display screen;
forming a phase compensation film layer on the first glue layer;
forming a second glue layer on the phase compensation film layer; and
forming a linear polarizer on the second glue layer.

16. (canceled)

17. The method of claim 15, wherein the forming the touch control electrode layer comprises:
forming a conducting bridge on a side of the linear polarizer opposite to the second glue layer when the circular polarizer is formed on the display screen and the touch control electrode layer is formed on the circular polarizer, or on one side of the phase compensation film layer by depositing a thin metal film layer via a first mask when the touch control electrode layer is formed on the display screen and the circular polarizer is formed on the touch control electrode layer or when the circular polarizer is formed on the display screen and the circular polarizer comprises the touch control electrode layer; depositing an insulating layer on the conducting bridge and forming vias corresponding to two electrodes of the conducting bridge by applying a second mask;
forming at least two touch-driving electrodes and a touch-sensing electrode by depositing a thin metal film layer on the insulating layer via a third mask, wherein the at least two touch-driving electrodes are connected to the conducting bridge through the vias, a gap is defined between the touch-sensing electrode and the touch-driving electrodes so as to form an induced capacitor.
